(19) United States
(12) Patent Application Publication
(10) Pub. No.: US 2007/0187842 A1
(43) Pub. Date: Aug. 16, 2007

(54) PRINTED CIRCUIT, METHOD OF MANUFACTURING THE PRINTED CIRCUIT, PRINTED CIRCUIT/ELECTRONIC ELEMENT ASSEMBLY, AND METHOD OF MANUFACTURING THE PRINTED CIRCUIT/ELECTRONIC ELEMENT ASSEMBLY

(76) Inventors: Sang-chul SHIN, Seongnam-si (KR); Woo-cheol Jeong, Anyang-si (KR)

Correspondence Address: STANZIONE & KIM, LLP, 919 18TH STREET, N.W., SUITE 440, WASHINGTON, DC, 20006, US

(21) Appl. No.: 11/673,230

(22) Filed: Feb. 9, 2007

(30) Foreign Application Priority Data
Feb. 10, 2006 (KR) 2006-12881

(51) Int. Cl. H01L 23/48

(52) U.S. Cl. 257/786

(57) ABSTRACT

Provided is a printed circuit. The printed circuit includes a base layer, a plurality of bonding pads formed on the base layer, and an insulation barrier formed between the bonding pads. The insulation barrier prevents a short circuit caused by whisker growth on solder portions electrically connecting the bonding pads to bonding portions of an electronic element.

### CROSS-REFERENCE TO RELATED APPLICATIONS

This application claims priority under 35 U.S.C. §119(a) from Korean Patent Application No. 10-2006-0012881, filed on Feb. 10, 2006, in the Korean Intellectual Property Office, the disclosure of which is incorporated herein in its entirety by reference.

### BACKGROUND OF THE INVENTION

1. Field of the Invention

The present general inventive concept relates to a printed circuit that can prevent a short circuit caused by whisker growth at a solder portion electrically bonding the printed circuit to an electronic element, a method of manufacturing the printed circuit, a printed circuit/electronic element assembly, and a method of manufacturing the printed circuit/electronic element assembly.

2. Description of the Related Art

As lead (Pb) has been determined to be an environmental pollutant, the use of lead has been restricted as an ingredient of solder cream used for electrically bonding a printed circuit to an electronic element. Recently, solder cream containing tin (Sn) as a main ingredient has been used.

FIG. 1 is a sectional view illustrating a conventional printed circuit/electronic element assembly.

In reference to FIG. 1, a conventional printed circuit/electronic element assembly 10 includes a printed circuit 20, an electronic element 11 loaded on the printed circuit 20, and a plurality of solder portions 25 electrically bonding the printed circuit 20 to the electronic element 11. The printed circuit 20 may be a flexible printed circuit having a base layer 21 and a plurality of bonding pads 23 formed on the base layer 21. The bonding pads 23 are connected to a plurality of bonding portions 14 via the respective solder portions 25. The solder portions 25 are formed by solder cream applied to the bonding pads 23 and dried. The solder cream does not contain Pb but instead contains Sn as a main ingredient. The reference number 12 indicates a molding body. For example, if the electronic element 11 is a semiconductor package, the molding body may be an encapsulation body. If the electronic element 11 is a connector, the molding body may be a housing.

Since the solder portions 25 contain the Sn as the main ingredient, Sn single crystal growth occurs at a given rate to form a whisker 30 on each solder portion 25. If the bonding portions 14 are coated with Sn, the whisker may be also formed on the bonding portions 14. Although the cause for formation of the whisker 30 is not clearly traced, it is thought that the whisker 30 is formed by a compressive residual stress of Sn accumulated during a soldering or coating process. The whisker 30 grows to interconnect adjacent solder portions 25 or adjacent bonding portions 14. This interconnection causes a short circuit of the printed circuit. Even when the whisker 30 grows only to a degree where the adjacent solder portions 25 or the adjacent bonding portions 14 are not interconnected, it may still detach to form a plasma arc causing a short circuit of the printed board.

### SUMMARY OF THE INVENTION

The present general inventive concept provides a printed circuit that can prevent a short circuit caused by whisker growth at a solder portion electrically bonding the printed circuit to an electronic element or between adjacent bonding portions, a method of manufacturing the printed circuit, a printed circuit/electronic element assembly, and a method of manufacturing the printed circuit/electronic element assembly.

Additional aspects and advantages of the present general inventive concept will be set forth in part in the description which follows and, in part, will be obvious from the description, or may be learned by practice of the general inventive concept.

The foregoing and/or other aspects and utilities of the present general inventive concept are be achieved by providing a printed circuit including a base layer, a plurality of bonding pads formed on the base layer, and an insulation barrier formed between the bonding pads to prevent a short circuit caused by whisker growth on solder portions electrically connecting the bonding pads to bonding portions of an electronic element.

The printed circuit may be a flexible printed circuit.

The insulation barrier may be formed by depositing photosensitive polyimide.

The foregoing and/or other aspects and utilities of the present general inventive concept are also be achieved by providing a printed circuit/electronic element assembly including a printed circuit including a base layer and a plurality of bonding pads formed on the base layer, an electronic element having a plurality of bonding portions bonded to the bonding pads, and solder portions electrically connecting the bonding pads to the bonding portions, wherein the printed circuit further includes an insulation barrier formed between the bonding pads to prevent a short circuit caused by whisker growth on solder portions.

The printed circuit may be a flexible printed circuit.

The insulation barrier may be formed by depositing photosensitive polyimide.

The electronic element may further include an insulation spacer formed between the bonding portions, and the insulation spacer contacts the insulation barrier.

The electronic element may be a connector to detachably connect the printed circuit to other circuits.

The foregoing and/or other aspects and utilities of the present general inventive concept are also be achieved by providing a printed circuit/electronic element assembly including a printed circuit including a base layer and a plurality of bonding pads formed on the base layer, an electronic element having a plurality of bonding portions bonded to the bonding pads, solder portions electrically connecting the bonding pads to the bonding portions, and an insulation layer formed by injecting insulation resin into a space defined between the printed circuit and the electronic element to prevent a short circuit caused by whisker growth on solder portions.

The insulation resin may include epoxy resin.

The printed circuit may be a flexible printed circuit.

The electronic element may be a connector for detachably connecting the printed circuit to other circuits.

The foregoing and/or other aspects and utilities of the present general inventive concept are also be achieved by providing a method of manufacturing a printed circuit, including forming a plurality of bonding pads on a base layer, and forming an insulation barrier between the bonding pads to prevent a short circuit caused by whisker growth on solder portions electrically connecting the bonding pads to bonding portions of an electronic element.

The insulation barrier may be formed by depositing photosensitive polyimide and etching the photosensitive polyimide to expose the bonding pads using a photolithography process.

The foregoing and/or other aspects and utilities of the present general inventive concept are also be achieved by providing a method of manufacturing a printed circuit/electronic element assembly, including providing a printed circuit which includes a plurality of bonding pads on a base layer and an insulation barrier between the bonding pads, and electrically connecting the bonding pads to bonding portions of an electronic element using solder portions such that the insulation barrier can be disposed between the soldering portions to prevent a short circuit caused by whisker growth on the solder portions.

The insulation barrier may be formed by depositing photosensitive polyimide and etching the photosensitive polyimide to expose the bonding pads using a photolithography process.

The foregoing and/or other aspects and utilities of the present general inventive concept are also be achieved by providing a method of manufacturing a printed circuit/electronic element assembly, including providing a printed circuit which includes a plurality of bonding pads on a base layer and an insulation barrier between the bonding pads, electrically connecting the bonding pads to bonding portions of an electronic element using solder portions, and forming an insulation layer by injecting insulation resin between the printed circuit and the electronic element to prevent a short circuit caused by whisker growth on the solder portions.

The insulation resin may include epoxy resin.

The foregoing and/or other aspects and utilities of the present general inventive concept are also be achieved by providing a printer circuit/electronic element assembly, including a printed circuit, including a base layer, a conductive layer formed on a surface of the base layer and patterned to have a plurality of bonding pads, and a cover layer formed on the patterned conductive layer, the cover layer patterned to have a plurality of barriers formed on sides of the bonding pads, and an electronic element having a plurality of bonding portions formed at a bottom surface thereof, wherein the barriers prevent whiskers from forming on solder portions used to electrically connect the bonding pads to the bonding portions.

The electronic element may further include a plurality of spacers formed on a bottom surface of the electronic element to contact the respective barriers.

The cover layer may include a photosensitive material.

The foregoing and/or other aspects and utilities of the present general inventive concept are also be achieved by providing a method of manufacturing a printed circuit, the method including patterning a conductive layer formed on a base layer to form a plurality of bonding pads, and forming a cover layer having a plurality of exposing portions on the conductive layer to expose the bonding pads and barriers disposed between adjacent bonding pads to prevent a formation of whiskers therebetween.

The forming of the cover layer may include forming the plurality of exposing portions on a film, and attaching the film on the conductive layer, wherein each of the plurality of exposing portions corresponds to a respective bonding pad and the barriers are formed between adjacent bonding pads to prevent a formation of whiskers therebetween when the film is attached.

The film may include a polyimide film.

The forming of the plurality of exposing portions may be performed through a punching process.

The forming of the cover layer may include forming the plurality of exposing portions on a film, wherein each exposing portion corresponds to a group of bonding pads, attaching the film on the conductive layer, depositing a photosensitive material on the film and exposed bonding pads, and removing portions of the photosensitive material covering individual bonding pads to form barriers between adjacent bonding pads to prevent a formation of whiskers therebetween.

The photosensitive material may include a photosensitive polyimide.

The removing of the portions of the photosensitive material may be performed through photolithography.

The forming of the cover layer may include depositing a photosensitive material on the conductive layer, and removing portions of the photosensitive material covering individual bonding pads to form barriers between adjacent bonding pads to prevent a formation of whiskers therebetween.

The forming of the cover layer may include depositing a first photosensitive material on the conductive layer, removing portions of the first photosensitive material covering groups of bonding pads, depositing a second photosensitive material on the exposed bonding pads, and removing portions of the second photosensitive material covering individual bonding pads to form barriers between adjacent bonding pads to prevent a formation of whiskers therebetween.

The first and second photosensitive materials may be the same material, and may be a photosensitive polyimide.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a sectional view illustrating a conventional printed circuit/electronic element assembly;

FIG. 2 is a top view illustrating an example of a hard disk drive;

FIG. 3 is a perspective view illustrating a printed circuit/electronic element assembly of FIG. 2 according to an embodiment of the present general inventive concept;

FIG. 4 illustrates a sectional view taken along line A-A′ of FIG. 3;

FIG. 5 illustrates a sectional view taken along line B-B′ of FIG. 3;

FIG. 6 is a sectional view illustrating a method of manufacturing a printed circuit according to an embodiment of the present general inventive concept;

FIG. 7 is a sectional view illustrating a printed circuit/electronic element assembly according to another embodiment of the present general inventive concept; and

FIG. 8 is a sectional view illustrating a printed circuit/electronic element assembly according to another embodiment of the present general inventive concept.

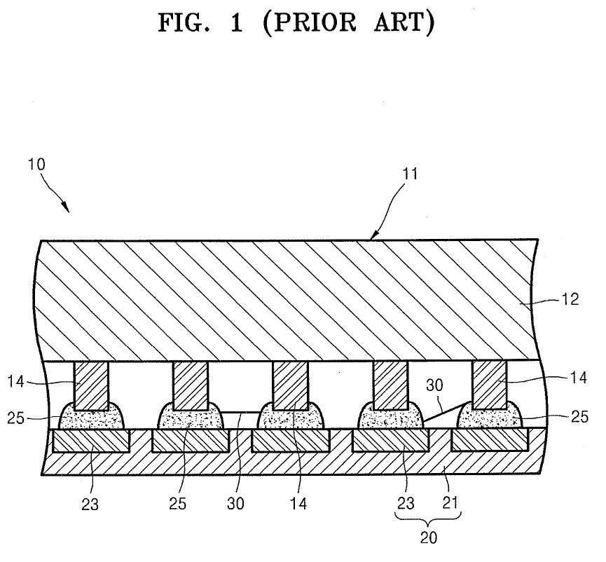

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

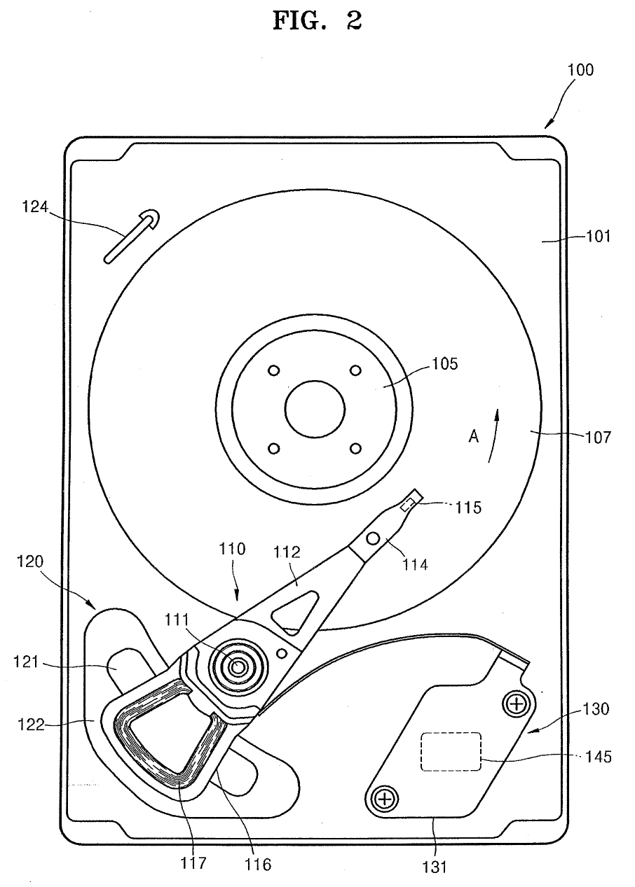

A printed circuit and a printed circuit/electronic element assembly according to the present general inventive concept may be applied to a variety of electronic elements, such as a hard disk drive that is used as a data storage device. FIG. 2 illustrates an example of a hard disk drive 100. After the hard disk drive 100 is first described with reference to FIG. 2, the printed circuit and the printed circuit/electronic element assembly that can be applicable to the hard disk drive will be described.

Referring to FIG. 2, the hard disk drive 100 may include a housing having a base member 101 and a cover member (not illustrated) coupled to the base member 101, a spindle motor 105, a data storage disk 107, a head stack assembly (HSA) 110, and a voice coil motor (VCM) block 120. The base member 101, spindle motor 105, data storage disk 107, HSA 110, and the VCM block 120 may be disposed in the housing. The spindle motor 105 is fixed on the base member 101 to rotate the data storage disk 107 at a high speed. The data storage disk 107 is coupled to the spindle motor 105 to rotate in a direction of arrow A. The high-speed rotation of the data storage disk 107 generates airflow above a surface of the data storage disk 107 in the direction of arrow A. A circulation filter 124 to filter off foreign objects, such as particles, contained in the air flowing above the surface of the data storage disk 107 can be installed at a corner portion of the base member 101.

The HSA 110 may include a head slider 115 having a magnetic head (not illustrated) to read and/or write data. The head slider 115 moves to a specific location of the data storage disk 107 to read or write the data from or to the data storage disk 107. The HSA 110 may further include a swing arm 112 mounted on the base member 101 and rotating about a pivot shaft 111, a suspension 114 coupled to a front end of the swing arm 112, and an over mold 116 coupled to the swing arm 112 and having a VCM coil 117. The head slider 115 can be loaded on a front end of the suspension 114.

When air passes through a space between the disk 107 and the head slider 115, a lift force is applied to the head slider 115. The head slider 115 maintains a floating state at a height where the lift force is equal to an elastic force of the suspension 114, which biases the head slider 115 toward the data storage disk 107. In this floating state, the magnetic head formed on the head slider 115 reads or writes the data from or to the data storage disk 107.

The VCM block 120 may be fixed on the base member 101 and the over mold 116 may be inserted into the VCM block 120 in a direction opposite to an extending direction of the swing arm 112 from the pivot 111. The VCM block 120 includes magnets 121 disposed above and below the over mold 116 and a yoke 122 supporting the magnets 121. The VCM coil 117 generates an electromagnetic force by cooperating with the magnet 121. The HSA 110 rotates by the electromagnetic force. The rotation of the HSA 110 may be controlled by a servo control system.

The HSA 110 can be electrically connected to a printed circuit/electronic element assembly 130 having a flexible printed circuit 131 and a connector 145 bonded to the flexible printed circuit 131. The printed circuit/electronic element assembly 130 can be coupled to a main circuit board (not illustrated) disposed under the base member 101 via the connector 145. Thus, the printed circuit/electronic element assembly 130 functions to exchange an electric signal between the HSA 110 and the main circuit board.

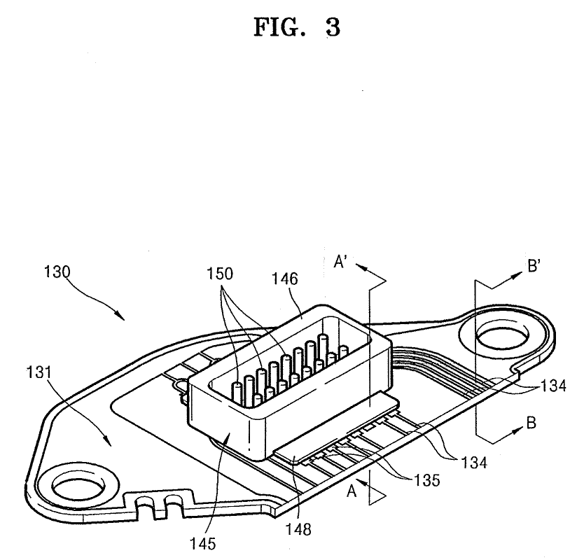

FIG. 3 is a perspective view illustrating the printed circuit/electronic element assembly of FIG. 2.

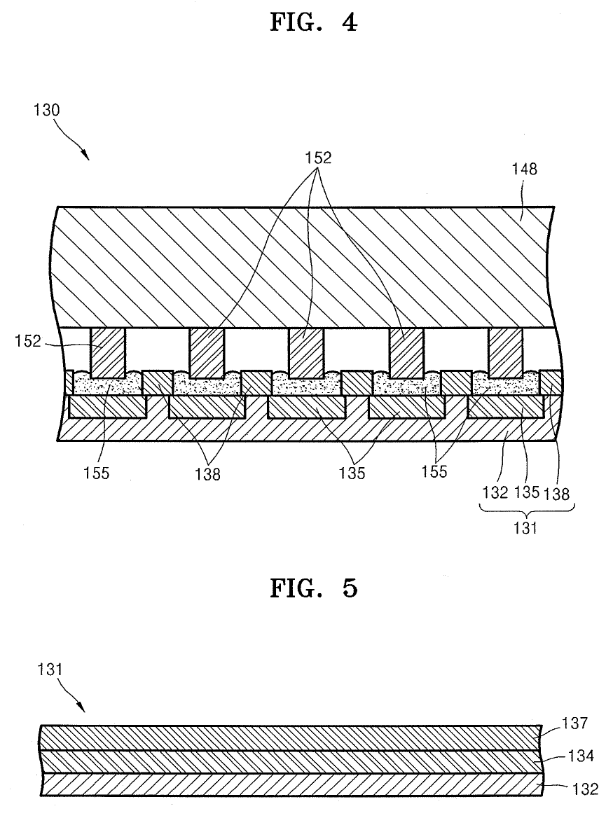

Referring to FIG. 3, the printed circuit/electronic element assembly 130 includes the flexible printed circuit 131 and the connector 145 as the electronic element. The connector 145 is loaded on the flexible printed circuit 131. The connector 145 may be a male connector 145 having a plurality of pins 150. The connector 145 may be detachably fitted to a female connector (not illustrated) that is loaded on the main circuit board disposed under the base member 101 of the hard disk drive 100 of FIG. 2. The connector 145 includes a housing 146 enclosing and protecting the pins 150. The housing 146 can be formed of resin. The housing 146 may include side extending portions 148. A plurality of bonding portions 152 extending from the pins 150 are provided on a bottom surface of the side extending portions 148 (see FIG. 4). The bonding portions 152 contact bonding pads 135 of the flexible printed circuit 131.

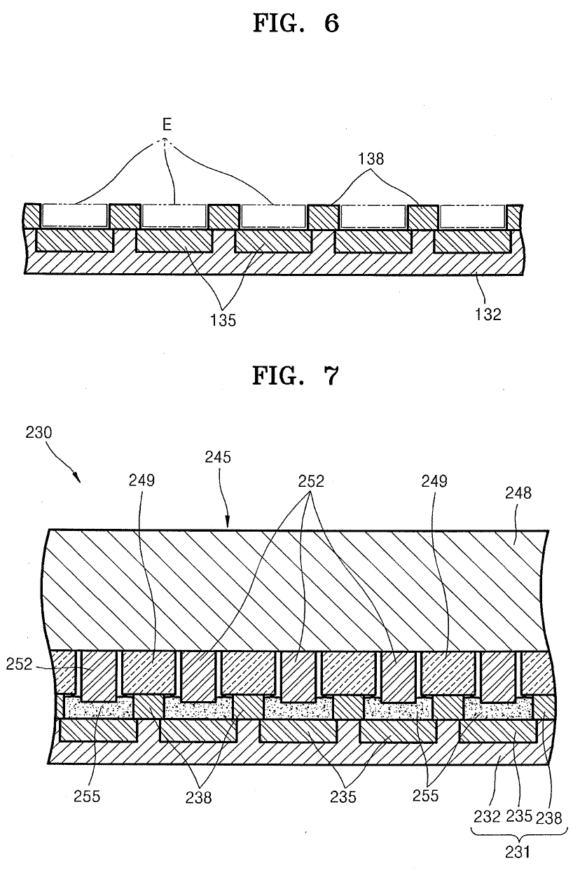

FIG. 4 illustrates a sectional view taken along line A-A′ of FIG. 3, FIG. 5 illustrates a sectional view taken along line B-B′ of FIG. 3, and FIG. 6 is a sectional view illustrating a method of manufacturing the printed circuit according to an embodiment of the present general inventive concept.

Referring to FIGS. 3 through 5, the flexible printed circuit 131 may include a flexible base layer 132, a conductive layer 134 patterned on the base layer 132, and a cover layer 137 protecting the conductive layer 134. The conductive layer 134 can be formed of copper (Cu). The base layer 137 and cover layer 137 may be formed of a polyimide film or by depositing photosensitive polyimide. A metal layer to reduce electromagnetic interference (EMI) may be formed under the base layer 132 (not illustrated).

A plurality of bonding pads 135 are provided at one end of the circuit pattern formed by the conductive layer 134. The bonding pads 135 are exposed such that they can be bonded to the bonding portions 152 by solder portions 155. The flexible printed circuit 131 may include insulation barriers 138 formed between the bonding pads 135. The insulation barriers 138 may be formed of polyimide film or by depositing photosensitive polyimide. This will be described in more detail later.

The solder portions 155 electrically bonding the bonding portions 152 to the bonding pads 135 are formed by hardening solder cream applied on the bonding pads 135. The solder cream does not contain Pb but instead contain Sn as a major ingredient. As illustrated in FIG. 4, the solder portions 155 are formed on the bonding pads 135. Then, the growth of whiskers is suppressed by the insulation barriers 138.

A method of manufacturing the flexible printed circuit 131 will now be described with reference to FIGS. 5 and 6.

When the base layer 132 and the cover layer 137 are formed of polyimide film, the conductive layer 134 is first attached on the base layer 132 and then the cover layer 137 is attached on the base layer 132 and the conductive layer 134. Before the cover layer 137 is attached on the base layer 132 and the conductive layer 134, exposing portions E to expose the bonding pads 135 are formed on the cover layer 137 through, for example, a punching process (See FIG. 6). Therefore, the portions of the cover layer 137, which remain between the exposing portions E and are attached on the base layer 132, serve as the insulation barriers 138.

However, when the connector (145 of FIG. 2) 145 of FIGS. 2 and 3, having a narrow pitch of less than 1 mm between the adjacent bonding portions 152, is loaded on the flexible printed circuit 131, a pitch between the adjacent bonding pads 135 must be narrowed in response to the pitch between the adjacent bonding portions 152. Therefore, it may be difficult to form the insulation barriers by punching the cover layer 137 formed of the polyimide film. In this case, photosensitive polyimide can be deposited on the conductive layer 134 and portions of the deposited photosensitive polyimide layer can be removed through etching, thereby forming the insulation barriers 138.

Describing the above process in more detail, the cover layer 137 formed of the polyimide film is provided with a large hole to expose the bonding pads 135 collectively and is then attached on the base layer 132 and the conductive layer 134. Next, the photosensitive polyimide is deposited on the region exposed by the hole of the cover layer 137, after which the deposited photosensitive polyimide layer is precisely etched to form the exposing portions E through a photolithography process which may include masking, photo exposure, and developing, thereby forming the insulation barriers 138 and exposing the bonding pads 135 as illustrated in FIG. 6.

Additionally, all of the base layer 132, the conductive layer 134 and the cover layer 137 may be formed through a deposition process. In this case, the insulation barriers 138 may be formed by precisely etching the cover layer 137 formed of deposited photosensitive polyimide to form the exposing portions E using a photolithography process which may include masking, photo exposure, and developing. Alternatively, the photosensitive polyimide can be first deposited to form the cover layer 137 and the cover layer 137 can be then etched using the photolithography process to expose the bonding pads 135 collectively. Then, photosensitive polyimide is further deposited on the exposed region of the bonding pads 135, after which the further deposited photosensitive polyimide is precisely etched to form the exposing portions E through the photolithography process, thereby forming the insulation barriers 138.

After forming the flexible printed circuit 131, the solder portions 155 are formed by applying solder cream on the bonding pads 135 and the bonding portions 152 of the connector (145 of FIG. 3) are bonded to the solder portions 155. Then, the solder portions 155 are hardened to complete the printed circuit/electronic element assembly 130.

FIG. 7 is a sectional view illustrating a printed circuit/electronic element assembly according to another embodiment of the present general inventive concept.

Referring to FIG. 7, a printed circuit/electronic element assembly 230 of this embodiment may include a flexible printed circuit 231 and an electronic element 245 bonded to the flexible printed circuit 231 to form a printed circuit/electronic element assembly 230. The electronic element 245 may be a connector, such as the connector 145 of FIG. 3. The flexible printed circuit 231 includes a base layer 232, a plurality of bonding pads 235 formed on the base layer 232, and insulation barriers 238 formed between the bonding pads 235. Since the flexible printed circuit 231 is similar to that of the embodiment of FIG. 4 and a method of manufacturing the flexible printed circuit 231 is also similar to that described with reference to FIGS. 5 and 6, the detailed description thereof will be omitted herein.

A housing 248 of the electronic element 245 can be formed of insulation molding resin. A plurality of bonding portions 252 that will be bonded to the bonding pads 235 are formed on a bottom surface of the housing 248. The electronic element 245 may further include spacers 249 formed between the bonding portions 252. The spacers 249 may contact the insulation barriers 238 as illustrated in FIG. 7. The insulation spacers 249 may be formed of insulation molding resin and integrally formed with the housing 248.

Solder portions 255 are formed by applying solder cream on the bonding pads 235 and the bonding portions 252 are bonded to the solder portions 255. Then, the solder portions 255 are hardened to complete the printed circuit/electronic element assembly 230. The solder cream does not contain Pb but instead contains Sn as a main ingredient.

As illustrated in FIG. 7, whisker growth on the solder portions 255 can be suppressed by the insulation barriers 238. Furthermore, since the insulation spacers 249 contacts the insulation barriers 238, the whisker growth on the solder portions 255 may be further suppressed and the whisker growth on the bonding portions 252 may also be suppressed.

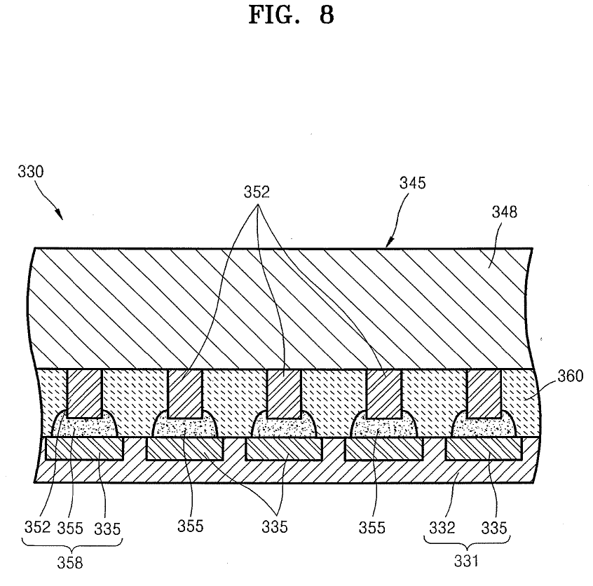

FIG. 8 is a sectional view illustrating a printed circuit/electronic element assembly according to another embodiment of the present general inventive concept.

Referring to FIG. 8, a printed circuit/electronic element assembly 330 of this embodiment may include a flexible printed circuit 331, an electronic element 345 bonded to the flexible printed circuit 331, an insulation layer 360 formed by injecting insulation resin between the flexible printed circuit 331 and a housing 348 of the electronic element 345. The electronic element 345 may be a connector such as the connector 145 of FIG. 3. The flexible printed circuit 331 may include a base layer 332 and a plurality of bonding pads 335 formed on the base layer 332. The housing 348 of the electronic element 245 can be formed of insulation molding resin. A plurality of bonding portions 352 that will be bonded to the bonding pads 335 are formed on a bottom surface of the housing 348. The insulation resin may be epoxy resin used to form an encapsulation of a semiconductor package or mixture resin containing the epoxy resin as a main ingredient.

A method of manufacturing the printed circuit/electronic element assembly 330 of FIG. 8 will now be described.

Solder portions 355 are formed by applying solder cream on the bonding pads 335 and the bonding portions 352 are bonded to the solder portions 355. Then, the solder portions 355 are hardened. Then, the insulation resin is injected between the flexible printed circuit 331 and the housing 348 of the electronic element 345 so that the insulation resin can be filled in spaces defined between connection units 358 each connection unit 358 formed of the bonding pad 335, solder portion 355, and bonding portion 352. The insulation resin is hardened to form the insulation layer 360.

The solder cream does not contain Pb but instead contains Sn as a main ingredient. However, as illustrated in FIG. 8, the whisker growth on the solder portions 355 and the bonding portions 352 can be suppressed by the insulation layer 360 formed between the connection units 358.

According to the present general inventive concept, a short circuit that may be caused by whisker growth generated on the bonding portions or the solder portions formed of material that does not contain Pb but instead contains Sn can be prevented.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A printed circuit comprising:
a base layer;
a plurality of bonding pads formed on the base layer; and
an insulation barrier formed between the bonding pads to prevent a short circuit caused by whisker growth on solder portions electrically connecting the bonding pads to bonding portions of an electronic element.

2. The printed circuit of claim 1, wherein the printed circuit is a flexible printed circuit.

3. The printed circuit of claim 1, wherein the insulation barrier is formed by depositing photosensitive polyimide.

4. A printed circuit/electronic element assembly comprising:
a printed circuit including a base layer and a plurality of bonding pads formed on the base layer;
an electronic element having a plurality of bonding portions bonded to the bonding pads; and
solder portions electrically connecting the bonding pads to the bonding portions,
wherein the printed circuit further includes an insulation barrier formed between the bonding pads to prevent a short circuit caused by whisker growth on solder portions.

5. The printed circuit/electronic element assembly of claim 4, wherein the printed circuit is a flexible printed circuit.

6. The printed circuit/electronic element assembly of claim 4, wherein the insulation barrier is formed by depositing photosensitive polyimide.

7. The printed circuit/electronic element assembly of claim 4, wherein the electronic element further includes an insulation spacer formed between the bonding portions, and the insulation spacer contacts the insulation barrier.

8. The printed circuit/electronic element assembly of claim 4, wherein the electronic element is a connector to detachably connect the printed circuit to other circuits.

9. A printed circuit/electronic element assembly comprising:
a printed circuit including a base layer and a plurality of bonding pads formed on the base layer;
an electronic element having a plurality of bonding portions bonded to the bonding pads;
solder portions electrically connecting the bonding pads to the bonding portions; and
an insulation layer formed by injecting insulation resin into a space defined between the printed circuit and the electronic element to prevent a short circuit caused by whisker growth on solder portions.

10. The printed circuit/electronic element assembly of claim 9, wherein the insulation resin includes epoxy resin.

11. The printed circuit/electronic element assembly of claim 9, wherein the printed circuit is a flexible printed circuit.

12. The printed circuit/electronic element assembly of claim 9, wherein the electronic element is a connector to detachably connect the printed circuit to other circuits.

13. A method of manufacturing a printed circuit, comprising:
forming a plurality of bonding pads on a base layer; and
forming an insulation barrier between the bonding pads to prevent a short circuit caused by whisker growth on solder portions electrically connecting the bonding pads to bonding portions of an electronic element.

14. The method of claim 13, wherein the insulation barrier is formed by depositing photosensitive polyimide and etching the photosensitive polyimide to expose the bonding pads using a photolithography process.

15. A method of manufacturing a printed circuit/electronic element assembly, comprising:
providing a printed circuit which includes a plurality of bonding pads on a base layer and an insulation barrier between the bonding pads; and
electrically connecting the bonding pads to bonding portions of an electronic element using solder portions such that the insulation barrier is disposed between the soldering portions to prevent a short circuit caused by whisker growth on the solder portions.

16. The method of claim 15, wherein the insulation barrier is formed by depositing photosensitive polyimide and etching the photosensitive polyimide to expose the bonding pads using a photolithography process.

17. A method of manufacturing a printed circuit/electronic element assembly, comprising:
providing a printed circuit which includes a plurality of bonding pads on a base layer and an insulation barrier between the bonding pads;
electrically connecting the bonding pads to bonding portions of an electronic element using solder portions; and
forming an insulation layer by injecting insulation resin between the printed circuit and the electronic element to prevent a short circuit caused by whisker growth on the solder portions.

18. The method of claim 17, wherein the insulation resin includes epoxy resin.

19. A printer circuit/electronic element assembly, comprising:
a printed circuit, comprising:
a base layer,
a conductive layer formed on a surface of the base layer and patterned to have a plurality of bonding pads, and
a cover layer formed on the patterned conductive layer, the cover layer patterned to have a plurality of barriers formed on sides of the bonding pads; and
an electronic element having a plurality of bonding portions formed at a bottom surface thereof,
wherein the barriers prevent whiskers from forming on solder portions used to electrically connect the bonding pads to the bonding portions.

20. The printer circuit/electronic element assembly of claim 19, wherein the electronic element further comprises:
a plurality of spacers formed on a bottom surface of the electronic element to contact the respective barriers.

21. The printer circuit/electronic element assembly of claim 19, wherein the cover layer comprises a photosensitive material.

22. A method of manufacturing a printed circuit, the method comprising:
patterning a conductive layer formed on a base layer to form a plurality of bonding pads; and
forming a cover layer having a plurality of exposing portions on the conductive layer to expose the bonding pads and barriers disposed between adjacent bonding pads to prevent a formation of whiskers therebetween.

23. The method of claim 22, wherein the forming of the cover layer comprises:
forming the plurality of exposing portions on a film; and
attaching the film on the conductive layer,
wherein each of the plurality of exposing portions corresponds to a respective bonding pad and the barriers are formed between adjacent bonding pads to prevent a formation of whiskers therebetween when the film is attached.

24. The method of claim 23, wherein the film comprises a polyimide film.

25. The method of claim 23, wherein the forming of the plurality of exposing portions is performed through a punching process.

26. The method of claim 22, wherein the forming of the cover layer comprises:
forming the plurality of exposing portions on a film, wherein each exposing portion corresponds to a group of bonding pads;
attaching the film on the conductive layer;
depositing a photosensitive material on the film and exposed bonding pads; and
removing portions of the photosensitive material covering individual bonding pads to form barriers between adjacent bonding pads to prevent a formation of whiskers therebetween.

27. The method of claim 26, wherein the photosensitive material comprises a photosensitive polyimide.

28. The method of claim 26, wherein the removing of the portions of the photosensitive material is performed through photolithography.

29. The method of claim 22, wherein the forming of the cover layer comprises:
depositing a photosensitive material on the conductive layer; and
removing portions of the photosensitive material covering individual bonding pads to form barriers between adjacent bonding pads to prevent a formation of whiskers therebetween.

30. The method of claim 29, wherein the material comprises photosensitive polyimide.

31. The method of claim 22, wherein the forming of the cover layer comprises:
depositing a first photosensitive material on the conductive layer;
removing portions of the first photosensitive material covering groups of bonding pads;
depositing a second photosensitive material on the exposed bonding pads; and
removing portions of the second photosensitive material covering individual bonding pads to form barriers between adjacent bonding pads to prevent a formation of whiskers therebetween.

32. The method of claim 31, wherein the first and second photosensitive materials are the same material.

33. The method of claim 32, wherein the material comprises photosensitive polyimide
